(19) United States
(12) Patent Application Publication
(10) Pub. No.: US 2025/0239484 A1
(43) Pub. Date: Jul. 24, 2025

(54) SELECTIVE FILM DEPOSITION

(71) Applicant: ASM IP Holding B.V., Almere (NL)

(72) Inventor: Paul Ma, Scottsdale, AZ (US)

(21) Appl. No.: 19/027,024

(22) Filed: Jan. 17, 2025

Related U.S. Application Data
(60) Provisional application No. 63/623,637, filed on Jan. 22, 2024.

(51) Int. Cl. H01L 21/768; C23C 16/04; C23C 16/455; C23C 16/56; H01L 21/3205; H01L 21/3213

(52) U.S. Cl. CPC H01L 21/76879; C23C 16/04; C23C 16/45525; C23C 16/56; H01L 21/32051; H01L 21/32136

(57) ABSTRACT

A method for selective deposition of a molybdenum film, comprising supporting a substrate in a reaction chamber, the substrate comprising a metal surface and an adjacent dielectric surface; selectively depositing the molybdenum film on the metal surface relative to the dielectric surface responsive to contacting the substrate with a first precursor containing a molybdenum oxyhalide in a cyclic deposition process; etching the molybdenum film responsive to contacting the substrate with a second precursor containing molybdenum halide in a cyclic etching process; and purging the reaction chamber.

### CROSS-REFERENCE TO RELATED APPLICATIONS

This application is a nonprovisional of, and claims priority to and the benefit of, U.S. Provisional Patent Application No. 63/623,637, filed Jan. 22, 2024 and entitled “SELECTIVE FILM DEPOSITION,” which is hereby incorporated by reference herein.

### FIELD OF INVENTION

The present disclosure relates generally to methods for selectively depositing molybdenum on a metal surface of a substrate relative to a dielectric surface and particularly to methods for depositing film in one or more features and/or forming a cap.

### BACKGROUND OF THE DISCLOSURE

Semiconductor fabrication processes for forming semiconductor device structures, for example, transistors, memory elements, and integrated circuits, are wide ranging and may include multiple cycles of deposition and etch processes.

In cyclic deposition and etch processes metal structures or surfaces on the substrate may be damaged during the cyclic process due to exposure to precursors used to deposit and/or etch other structures. Accordingly, it is desirable to develop semiconductor fabrication processes that reduce or eliminate such collateral damage.

### SUMMARY OF THE DISCLOSURE

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

In some aspects a method for selective deposition of a molybdenum film is provided, comprising supporting a substrate in a reaction chamber, the substrate comprising a metal surface and an adjacent dielectric surface; selectively depositing the molybdenum film on the metal surface relative to the dielectric surface responsive to contacting the substrate with a first precursor containing a molybdenum oxyhalide in a cyclic deposition process; etching the molybdenum film responsive to contacting the substrate with a second precursor containing molybdenum halide in a cyclic etching process; and purging the reaction chamber.

The disclosed method may include repeating one or more of the previously noted steps any number of times, in any order or combination thereof until the molybdenum film reaches a first desired thickness on the metal surface.

The disclosed method may include repeating one or more of the previously noted steps any number of times, in any order or combination thereof until the molybdenum film reaches a second desired thickness on the dielectric surface.

The disclosed method may include wherein the metal surface comprises copper (Cu) or cobalt (Co), or a combination thereof.

In some examples the dielectric surface comprises low-k material.

In particular examples the first precursor contains MoO₂Cl₂ and wherein the second precursor contains MoCl₅.

In some examples selectively depositing the molybdenum film is carried out using plasma enhanced atomic layer deposition (PEALD) at a temperature less than about 350° C.

In certain examples etching the molybdenum film is carried out at a temperature greater than about 350° C.

In particular examples the method further comprises precleaning the metal surface and dielectric surface responsive to contacting the substrate with an H₂ plasma.

In some examples the method further comprises selectively depositing a passivation film on the dielectric surface relative to the metal surface responsive to contacting the substrate with a second precursor comprising an alkylaminosilane. In some examples the passivation film is deposited prior to the selectively depositing the molybdenum film.

In particular examples the alkylaminosilane comprises at least one of allyltrimethylsilane (TMS-A), chlorotrimethylsilane (TMS-Cl), N-(trimethylsilyl)imidazole (TMS-Im), octadecyltrichlorosilane (ODTCS), hexamethyldisilazane (HMDS), N-(trimethylsilyl)dimethylamine (TMSDMA) or trimethylchlorosilane, or a combination thereof.

In particular examples the etching the molybdenum film further comprises removing the molybdenum film that deposited on the passivation film during the cyclic deposition process.

The disclosed method may include repeating one or more of the previously noted steps any number of times, in any order or combination thereof until the molybdenum film reaches a third desired thickness on the passivation film.

The method of claim 14, further comprising removing the passivation film responsive to contacting the substrate with a plasma.

In some examples contacting the substrate with a first precursor takes place within a feature.

The method of claim 15, wherein the feature is a via or trench, or combination thereof.

In some examples the feature is a dual damascene feature having a via contiguous with a trench.

In particular examples the metal surface forms an inner surface of the via and wherein the dielectric surface forms inner sidewalls of the trench.

In examples the selectively depositing the molybdenum film further comprises depositing the molybdenum film on the inner surface of the via to a thickness sufficient to at least partially fill the via from the inner surface up.

In particular examples the selectively depositing the molybdenum film further comprises depositing the molybdenum film in an unwanted layer on a portion of the inner sidewalls of the trench.

In some examples the method further comprises oxidizing the unwanted layer of the molybdenum film on the portion of the trench responsive to contacting the molybdenum film with an oxidizer; and etching the unwanted layer responsive to contacting the substrate with the second precursor. The disclosed method may include repeating one or more of the previously noted steps any number of times, in any order or combination thereof repeating steps e or f or a combination thereof until the unwanted layer has been etched to a desired thinness on the portion of the inner sidewalls of the trench. In some examples, the etching the unwanted layer further comprises removing substantially all of the unwanted layer.

In some examples the oxidizer comprises at least one of: water (H₂O), hydrogen peroxide (H₂O₂), ozone (O₃), oxygen (O₂), O₂ plasma, alcohol, alkyl alcohol, ethanol, methanol, butanol, isobutanol, isopropanol, or a combination thereof. the etching may be carried out at a first temperature above a second temperature at which the selective deposition is carried out.

In particular examples the selectively depositing the molybdenum film further comprises a plasma enhanced atomic layer (PEALD) deposition process, comprising, alternately and sequentially contacting the substrate with the first precursor containing MoO₂Cl₂ and a reactant comprising reactive species from a plasma. In some examples the reactive species is H₂.

Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

### BRIEF DESCRIPTION OF THE DRAWING FIGURES

While the specification concludes with claims particularly pointing out and distinctly claiming what are regarded as examples of the invention, the advantages of examples of the disclosure may be more readily ascertained from the description of certain examples of the examples of the disclosure when read in conjunction with the accompanying drawings, in which:

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates simplified cross-sectional schematic diagrams of semiconductor structures formed during cyclic processes, in accordance with an example of the present technology.

FIG. 4 illustrates simplified cross-sectional schematic diagrams of semiconductor structures formed during cyclic processes, in accordance with an example of the present technology.

FIG. 5 illustrates a processing method, in accordance with an example of the present technology.

FIG. 6 illustrates a processing method, in accordance with an example of the present technology.

FIG. 7 illustrates a processing method, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), “molecular beam epitaxy” (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition. As used herein the term chemical vapour deposition can refer to any process wherein the substrate is exposed to one or more volatile precursors.

As used herein, the terms “cyclic deposition” may refer to the sequential introduction of one or more precursors and/or reactants into a reaction chamber to deposit a film over a substrate and includes deposition techniques such as atomic layer deposition, cyclic chemical vapor deposition and/or other appropriate techniques.

As used herein, the terms “cyclic etch” may refer to the sequential introduction of one or more precursors and/or reactants into a reaction chamber to etch a film over a substrate and includes etch techniques such as plasma etching, wet etching, dry etching, vapor etching, atomic layer etching and/or other appropriate etching techniques.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

As used herein, the term “feature” may refer to a protrusion, an opening, a texture, or cavity disposed in or on one or more surfaces of a substrate.

The term “gap feature” may refer to an opening or cavity disposed between opposing inclined sidewalls of two protrusions, such as gaps, vias, trenches, and the like, extending vertically from the surface of the substrate or opposing inclined sidewalls of an indentation extending vertically into the surface of the substrate, such a gap feature may be referred to as a “gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

The term “dual damascene feature” may refer to a trench coupled to a via or a trench contiguous with a via. Such features are patterned during the backend-of-the-line (BEOL) stage of the semiconductor manufacturing process to fabricate interconnects within a device. In some examples, the dual damascene process may include metallization with copper and/or cobalt.

The present disclosure includes cyclic deposition-etch processes for selective deposition of molybdenum film on a metal surface relative to a low-k surface where the metal surface and the low-k surface are adjacent. In some examples, the metal surface and the low-k surface form a feature in or on a substrate. Such molybdenum film may be utilized in a number of applications, such as, for example, low electrical resistivity gap-fill, cap or liner layers, DRAM word-line features, DRAM buried word-line features or as an interconnect material in CMOS logic applications. The ability to selectively deposit a molybdenum film may allow for lower effective electrical resistivity for interconnects in logic applications, i.e., CMOS structures, capping structures, back end of line (BEOL) and word-line/bit-line in memory applications.

As used herein, “Plasma Enhanced Atomic Layer Deposition” (PEALD) refers to a film deposition technique that utilizes a plasma to enhance ALD processing. Plasma contains highly activated species such as ions, electrons and radicals that interact with the precursors for the desired material deposition on the substrate. In some embodiments, the activated species react with precursor molecules by breaking chemical bonds and creating a reactive species.

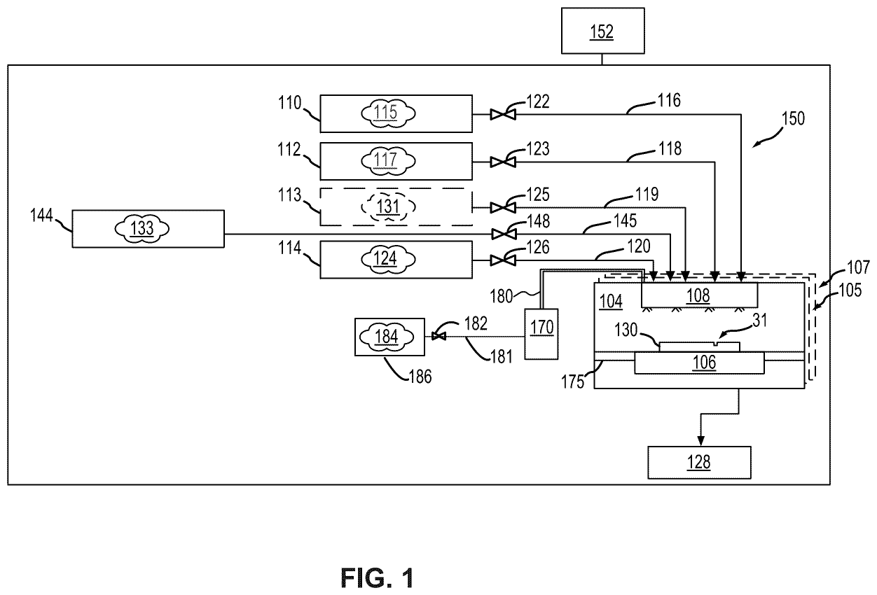

In some examples of PEALD, a plasma is introduced into the reaction chamber directly, as in direct plasma (e.g., direct plasma source 175 shown in FIG. 1) where in the plasma is generated in the reaction chamber. The direct plasma can be created using various methods, such as radio frequency (RF), microwave, or other energy sources. In some examples of PEALD, a plasma is introduced into the reaction chamber from a remote plasma source. The remote plasma can be generated in a separate chamber or region (e.g., remote plasma unit 170 shown in FIG. 1). Activated species are then transported to the reaction chamber where the precursors and substrate are located.

One of the advantages of PEALD is its ability to operate at lower temperatures compared to some examples of ALD or CVD processes. PEALD allows for enhanced reactivity of precursors enabling deposition to occur at lower temperatures while maintaining high quality films. Thus, using PEALD techniques reduces risk of damage to certain films on substrates sensitive to temperatures above the PEALD operating or reaction temperature. PEALD also reduces overall thermal budget for a process by lowering the deposition temperature which can be significant for certain materials in device manufacturing. Lower temperatures can also improve step coverage thus ensuring that the deposited film conforms well to complex substrate topographies.

FIG. 1 is a schematic illustration representing an abstraction of an example reactor system 150. Reactor system 150 may comprise one or more reaction chambers 104, 105 and 107, each housing a susceptor 106 to hold a substrate 130 (including at least one feature 31) during processing, a fluid distribution system 108 (e.g., a showerhead) to distribute one or more reactants to a surface of substrate 130. Reactor system 150 may include a direct plasma source 175 incorporated within any of chambers 104, 105 or 107 and/or a remote plasma source 170 coupled to any of chambers 104, 105 or 107. Multiple deposition and/or etching processes may be carried out in a single reaction chamber 104 and/or various processes may be carried out in separate reaction chambers 104, 105 and/or 107.

For simplicity, reactant sources and carrier/purge gas sources are shown coupled to a single reaction chamber 104, however, it should be understood that reactant sources and carrier/purge gases for separate processes to be carried out in separate reaction chambers may be coupled to respective reaction chambers for those specific processes.

In an example, reactant (or gas) source vessels 110, 112, 113, 144, 186 and/or a carrier or purge gas source vessel 114, may be fluidly coupled to reaction chamber 104 via respective lines 116, 118, 119, 145, 181 (via RPU 170 and transport tube 180) and 120. Respective valves or controllers 122, 123, 125, 148, 182 and 126 may controlled flow of reactants and gases into chamber 130. Reactant gases (e.g., first vapor phase precursor 115, second vapor phase precursor 117, oxidizer 131, plasma gas 184, and/or inhibitor 133) or other materials from respective source vessels can be applied to substrate 130 in reaction chamber 104. Carrier or purge gas 124 from gas source vessel 114 may be an inert gas and can be flowed to and through reaction chamber 104 to remove any excess reactant or other undesired materials from reaction chamber 104. System 150 can also comprise a vacuum source 128 fluidly coupled to the reaction chamber 104, which can be configured to evacuate reactants, a purge gas, or other materials out of reaction chamber 104. Carrier or purge gas 124 may comprise argon, helium, neon, krypton, nitrogen and/or xenon, or the like, or combination thereof.

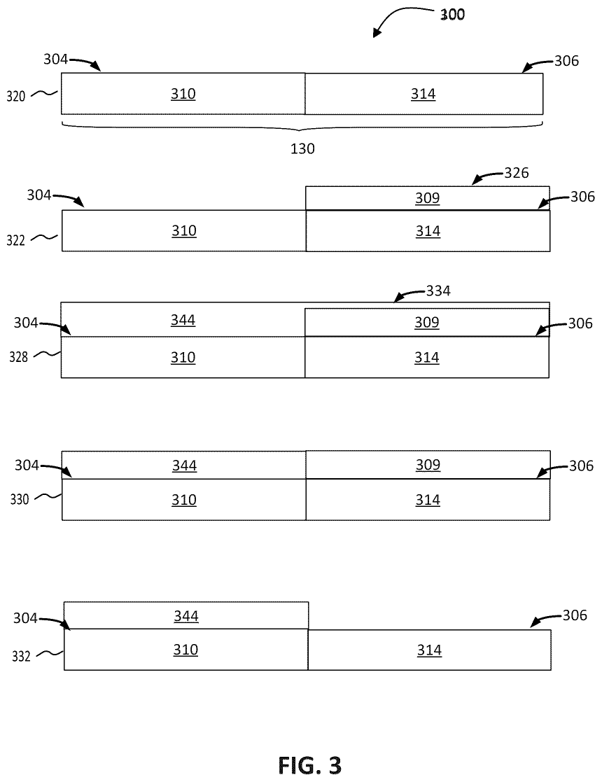

In an example, controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of example, controller 152 can be used to control gas flow (e.g., by monitoring flow rates and controlling valves 122, 123, 125, 126, 182 and/or 148), motors, showerhead 108, remote plasma source 170, heaters, cooling devices and/or vacuum source 128 to execute various processes (e.g., processes 300, 400, 500, 600, and/or 700 shown in respective FIGS. 3, 4, 5, 6, and/or 7). Further, when a system includes two or more reaction chambers, as described in more detail below, the two or more reaction chambers can be coupled to the same/shared controller.

In an example, system 150 may perform a selective deposition process to selectively deposit molybdenum onto a metal surface relative to a dielectric surface. The metal surface and the dielectric surface may be adjacent and lateral or side by side within a feature (including a dual damascene feature) formed on the substrate. The selective deposition may be carried out on such a lateral surface or within such a feature. The process may comprise a plurality of deposition and etch sub-cycles starting with depositing a thin molybdenum layer, etching the molybdenum layer from unwanted areas of the dielectric surface and repeating the process until the molybdenum layer reaches a desired thickness on the metal surface and/or is removed from the dielectric surface or is sufficiently etched to a desired thinness on the dielectric surface. In the etching sub-cycle, the molybdenum film may be etched to leave a molybdenum layer in the bottom portion of feature 31 of substrate 130. The process may include deposition using PEALD techniques and/or oxidising the surface of the selectively deposited molybdenum layer to improve etching efficiency.

In a first sub-cycle, selectively depositing the molybdenum layer on a metal surface adjacent a dielectric surface of substrate 130 may comprise pulsing first vapor phase precursor 115 from reactant source vessel 110 to reaction chamber 104 via showerhead 108. In an example, first precursor 115 may comprise MoO₂Cl₂.

In an etching sub-cycle, etching the molybdenum film from the dielectric surface or other areas where molybdenum deposition is not desired may be carried out by contacting substrate 130 with a second vapor phase precursor 117. The second vapor phase precursor 117 may be pulsed from reactant source vessel 112 to reaction chamber 104 via showerhead 108. In an example, second precursor 117 may contain MoCl₅. The first deposition sub-cycle and/or the etching sub-cycle may be repeated until the molybdenum film reaches a desired thickness on the metal surface and/or molybdenum film deposited in unwanted areas has been removed or sufficiently thinned.

Selectively depositing the molybdenum film may include additional process steps as will be described in greater detail below. For example, process steps may include oxidizing the molybdenum film by pulsing and oxidizer 131 from vessel 113 into the chamber 104 via showerhead 108 in order to improve etching efficiency. In other examples, a plasma may be supplied to chamber 130 from remote plasma unit 170 during selective deposition of molybdenum film. In another example, an inhibitor 133 may be supplied to chamber 104 from source vessel 144 via shower head 108 to selectively deposit a passivation layer on the dielectric surface. The process steps may further include purging the chamber with a purge gas 124 from vessel 114 to chamber 104 via showerhead 108 between one or more pulses of the first vapor phase precursor 115, the second vapor phase precursor 117, oxidizer 131, inhibitor 133, plasma and other precursors or reactants and/or between one or more deposition or etching cycles. Deposition or etching sub-cycles (or portions thereof) may be repeated until a desired thickness of molybdenum film is deposited on the metal surface and where unwanted molybdenum deposition is removed or thinned to a desired thickness.

First vapor phase precursor 115, oxidizer 131 and/or second vapor phase precursor 117 may be pulsed into the chamber in various orders and/or one or more may be pulsed simultaneously. For example, a deposition cycle for selectively depositing molybdenum film on a metal surface within feature 31 relative to a dielectric surface may comprise pulsing first vapor phase precursor 115 into chamber 104 to deposit the molybdenum film; purging chamber 104 with purge gas 124; then, pulsing oxidizer 131 to oxidize an exposed surface of deposited molybdenum film deposited on undesirable areas (e.g., dielectric surfaces) to enhance etching; then, purging chamber 104 with purge gas 124; and finally, pulsing second vapor phase precursor 117 into chamber 104 to etch the molybdenum film from areas where molybdenum film deposition was not intended substantially completely and/or to an acceptable thinness. In other words, chamber 104 may be purged with purge gas 124 before, after, between, one or more pulses of any of first vapor phase precursor 115, second vapor phase precursor 117 and oxidizer 131 and/or between one or more sub-cycles. The deposition and/or etch sub-cycles (or portions thereof) may be repeated until a desired thickness of molybdenum film is disposed on the metal surface.

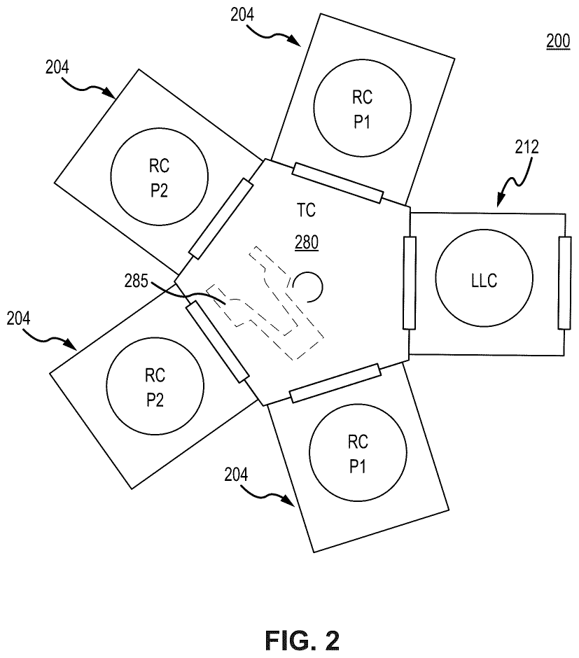

In some examples, a reactor system (e.g., reactor system 150) can comprise multiple reaction chambers. For example, in reactor system 200, shown in FIG. 2, a number of reaction chambers 204 (each of which can be an example of any of reaction chambers 104, 105, and/or 107 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 130 can be disposed in different chambers for different steps of a semiconductor manufacturing process (e.g., deposition, etching, oxidizing, and/or passivation steps may each be performed in the same or different chambers).

FIG. 3 illustrates a process 300 for selective deposition of molybdenum on a substrate 130, wherein operations of process 300 are depicted in cross-sectional views of substrate 130.

In an example, substrate 130 comprises a first material 310 having a first surface 304 and a second material 314 having second surface 306. In an example, first material 310 and second material 314 may be different materials.

In an example, first material 310 and/or first surface 304 can comprise or be defined by a metallic material, elemental metal, a metallic surface, or a combination thereof. In some examples, first surface 304 may comprise aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or the like, or a combination thereof. In an example, second material 314 and/or second surface 306 can comprise an inorganic dielectric, such as a low-k layer (typically a silicon oxide-based layer) or a silicon surface having native oxide (also a form of silicon oxide) formed thereover. Examples of low-k material include silicon oxide-based materials, including grown or deposited silicon dioxide, doped and/or porous oxides, native oxide on silicon, etc. In certain examples, second material 314 and/or second surface 306 can comprise SiCOx, SiOx, SiO2, SiC, SiOC, SiON, SiOCN, SiGe, SiN, Si, or the like or a combination thereof.

The following description of process 300 is with reference to FIGS. 1 to 3.

In an example, process 300 starts at operation 320 wherein a substrate 130 having a first surface 304 and a second surface 306 is supported in a reaction chamber 104 (see FIG. 1). In some examples, first material 310 and second material 314 may be materially different thus exposed first surface 304 and second surface 306 may be materially different. In an example, at operation 320 process 300 may begin with a pre-clean step to remove surface impurities and/or oxides from surfaces 304 and 306. Surface cleaning may be carried out using plasma cleaning techniques such as H₂-based plasma. The plasma may be generated in-situ by a direct plasma device 175 or generated remotely by a remote plasma unit (RPU) 170.

Process 300 may continue to operation 322 where selective deposition of passivation layer 309 over second surface 306 may be performed. Passivation layer 309 having third surface 326 may be formed selectively on second surface 306 relative to first surface 304.

In an example, selectively depositing the passivation layer comprises contacting the substrate 130 with an inhibitor (e.g., inhibitor 133) comprising an alkylaminosilane. In an example, inhibitor 133 may comprise allyltrimethylsilane (TMS-A), 1,1,1-Trimethoxy-N,N-dimethylsilanamine, chlorotrimethylsilane (TMS-Cl), N-(trimethylsilyl) imidazole (TMS-Im), octadecyltrichlorosilane (ODTCS), hexamethyldisilazane (HMDS), N-(trimethylsilyl) dimethylamine (TMSDMA), 1,1,1-Trimethoxy-N,N-dimethylsilanamine, or trimethylchlorosilane, or a combination thereof.

In an example, inhibitor 133 may be provided to the reaction chamber 104 holding the substrate 130 to contact substrate 130 with a single pulse or in a sequence of multiple pulses. In some embodiments the inhibitor 133 is provided in a single long pulse or in multiple shorter pulses. The pulses may be provided sequentially. In some embodiments inhibitor 133 is provided in 1 to 1000 pulses of from about 0.01 to about 600 seconds, or any appropriate number of pulses of any appropriate duration. In between pulses, inhibitor 133 may be removed from the reaction space. For example, the reaction chamber 104 may be evacuated and/or purged with an inert gas. The purge may be, for example for about 0.01 to 600 seconds, or any appropriate pulse period.

In some embodiments, the temperature of the passivation process may be, for example, from about 25° C. to 500° C., or about 100° C. to about 300° C., or any appropriate temperature. The pressure during the passivation process may be, for example, from about 0.01 to about 760 Torr, or in some embodiments from about 1 to 10 Torr or about 0.1 to about 10 Torr.

Process 300 may continue to operation 328 where selective deposition of third material layer 344 is carried out to deposit third material layer 344 on first surface 304 relative to surface 326 of passivation layer 309. In an example, selectively depositing third material layer 344 comprises contacting the surface 304 with first precursor 115.

In an example, first precursor 115 may comprise a metal precursor and/or a metallic precursor. In some examples, the first vapor phase precursor 115 may comprise a metal halide precursor, such as, for example, a metal chloride precursor, a metal iodide precursor, or a metal bromide precursor. In particular examples, the metal halide precursor may comprise: molybdenum (IV) dichloride dioxide (MoO₂Cl₂), molybdenum tetrachloride (MoCl₄), molybdenum pentachloride (MoCl₅), molybdenum (V) trichloride oxide (MoOCl₃), molybdenum (VI) tetrachloride oxide (MoOCl₄), indium trichloride (InCl₃), tantalum pentachloride (TaCl₅), tungsten hexachloride (WCl₆), vanadium fluoride (VF₃), vanadium chloride (VCl₃), vanadium oxychloride (VOCl₃), zirconium tetrachloride (ZrCl₄), titanium tetrachloride (TiCl₄), titanium tetraiodide (TiI₄), titanium tetrabromide (TiBr₃), hafnium tetrachloride (HfCl₄), boron trichloride (BCl₃), aluminum trichloride (AlCl₃), silicon tetrachloride (SiCl₄), disilicon hexachloride (Si₂Cl₆), 2-methylcyclohexa-2,5-diene-1,4-diyl) bis(trimethylsilane) (Cl₃H₂₆Si₂), triethyl borate (B(OCH₂CH₃)₃), trisilicon octochloride (Si₃Cl₈), dichlorosilane (SiH₂Cl₂), NiCl₂(TMPDA), gallium monochloride (GaCl), gallium trichloride (GaCl₃), or niobium pentachloride (NbCl₅), or the like or combinations thereof.

In an example, third material layer 344 may comprise the same material as material 310 or may be any of a variety of different materials. For example, third material layer 344 may be a metal (e.g., including but not limited to Mo, Al, Cu, W, Co, Nb, Ru, Ti, Ta or V or any combination thereof), metal oxide (e.g., any metal oxide including but not limited to AlOx, CoOx, CrOx, GaOx, HfOx, MnOx, MoOx, NbOx, NiOx, RuOx, SiCOx, SiOx, TaOx, TiOx, WOx, ZnOx, or ZrOx, or any combination thereof), metal nitride (e.g., a metal nitride including but not limited to TaN, MoNx, WNx, or TiN or any combination thereof), metal carbide (e.g., metal carbides including but not limited to VCx, MoCx, NbCx, TaCx, TiCx, or WCx or any combination thereof), silicon oxynitrides or silicon oxycarbides, or any combination thereof or any other appropriate material. In some examples of the disclosure, contacting substrate 130 with first precursor 115 may comprise contacting the substrate for a time period of between about 0.01 seconds and about 60 seconds, or between about 0.05 seconds and about 10 seconds, or between about 0.1 seconds and about 5.0 seconds, or even between 0.2 seconds and 1 second, or any appropriate time period.

In an example, selective deposition of material 344 at operation 328 may be carried out using a PEALD process. In such an example, contacting surface 304 with precursor 115 may comprise generating a plasma to activate precursor 115. The plasma may be generated remotely in an RPU (e.g., RPU 170) and transported to reaction chamber 104 via transport tube 180. Alternatively, a plasma may be generated in-situ by a direct plasma device (e.g., direct plasma device 175). The plasma may be formed by exciting a plasma gas source (e.g., plasma source gas 184, see FIG. 1). There are a variety of activated plasma species such as ions, electrons and radicals that may interact with precursor 115 to deposit third layer 344 (e.g., molybdenum) on surface 304. For example, the plasma generated may be an excited species comprising electrons, ions, radicals and/or atoms of hydrogen, argon, neon, krypton, nitrogen, helium, xenon, radon, chlorine, fluorine, or oxygen or a combination thereof. In an example, third material layer 344 may comprise molybdenum deposited using PEALD and first precursor 115 may comprise MoO₂Cl₂. Using the PEALD technique may allow for use of lower temperatures (e.g., less than about 400° C., or less than about 375° C., or less than about 350° C., or any appropriate temperature) to deposit molybdenum using various precursors including MoO₂Cl₂. In an example wherein material 344 is molybdenum deposited on a first surface 304 comprising copper, use of a PEALD to deposit molybdenum with MoO₂Cl₂ may reduce etching or other damage to the first surface 304 or deeper into the copper layer.

Process 300 may continue to operation 330 where etching of third material layer 344 is carried out to remove third material layer 344 from third surface 326 of passivation layer 309. In an example, etching third material layer 344 comprises contacting the surface 334 with second precursor 117. The cyclic etching sub-cycle may be repeated until third material layer 344 is etched to a predetermined thickness. In a particular example, such a cyclic etching sub-cycle, may be repeated to etch back third material layer 344 to form a cap over first material layer 310 (e.g., forming a molybdenum cap on a copper layer adjacent to a low-k layer). In an example, etching may comprise a thermal atomic layer etching step. In some examples, the etching may be performed on a variety of materials forming third material layer 344 described herein including a molybdenum film.

In an example, the etching at operation 330 may start by contacting third material layer 344 with a halide (e.g., second precursor 117 in FIG. 1). Such an etchant can be useful in increasing or maintaining desired selectivity and has an added benefit of removing metal oxides from the substrate surface and/or cleaning dielectric material of residue. An exemplary etchant may include molybdenum pentachloride (MoCl₅). Other etchants may be used including other metal halides, such as tungsten chloride (WCl₅), chlorine (Cl₂), niobium chloride (NbCl₅), titanium tetrachloride (TiCl₄), vanadium tetrachloride (VCl₄), tantalum pentachloride (TaCl₅), hafnium tetrachloride (HfCl₄), niobium fluoride (NbF₅), tantalum chloride (TaCl₅), or tantalum fluoride (TaF₅), or NF₃, or the like or a combination thereof. The etching sub-cycle may be carried out at temperatures higher than deposition of the third material layer 344 (e.g., greater than about 300° C., or greater than about 350° C., or greater than about 400° C., or any appropriate temperature).

In an example, a concentration of second precursor 117 may impact etching activity. In an example, reactant vessel 140 temperature may be maintained at about 100° C. to 150° C. to maintain a faster or desired etch rate. In an example, a higher reactant vessel 140 temperature provides a higher dose of second precursor 117. In certain examples, second precursor 117 may be exposed to a remote, indirect, or direct plasma prior to reaching the surface of the substrate.

In an example, operations 328 and 330 may be repeated until a desired thickness of third material layer 344 is achieved and until third material layer 344 is etched completely from surface 306 or thinned to a negligible or otherwise acceptable thickness on surface 306. In an example, a first desired thickness of third material layer 344 disposed on first surface 304 may be between about 2.0 angstrom (Å)-100.0 Å, or between about 5.0 Å-80.0 Å, or between about 10.0 Å-70.0 Å, or between about 15.0 Å-65.0 Å, or between about 20.0 Å-50.0 Å, or any appropriate thickness. Whereas, a second desired thickness of third material layer 344 disposed on second surface 306 may be less than about 2 A, or less than about 1 Å, or any appropriate thickness. In some embodiments, the etching sub-cycles would etch the third material layer 344 completely off of second surface 306.

Process 300 may continue to operation 332, where passivation layer 309 may be completely or almost completely removed by exposing the substrate 130 to a removal agent (e.g., plasma source gas 184, see FIG. 1). In certain examples the removal agent may be a plasma or O3. In some examples, an etch process may be employed to remove passivation layer 309 comprising exposing the substrate to a plasma. The plasma may be generated in RPU 170 and transported via transport tube 180 to chamber 104 or by direct plasma device 175 within chamber 104.

In some examples, a gas 184 for plasma formation may be supplied from source vessel 186 to RPU 170. The plasma may comprise oxygen atoms, oxygen radicals, oxygen plasma, or combinations thereof. In some examples, the plasma may comprise hydrogen atoms, hydrogen radicals, hydrogen plasma, or combinations thereof. In some examples, the plasma may comprise NH3 molecules, NH3 plasma, or combinations thereof. In some examples, the plasma may comprise inert gas species, for example Ar, N2 or He species. In some examples the plasma may comprise inert gas species. In some instances, the plasma may comprise other species, for example nitrogen atoms, nitrogen radicals, nitrogen plasma, or combinations thereof. The removal of passivation layer 309 by exposure to a plasma removal agent may continue until the passivation layer 309 is substantially removed having a desired thickness of less than about 2 Å, or less than about 1 Å, or a negligible thickness or completely removed.

In some examples, the passivation layer 309 removal process may be an etching process comprising exposing the substrate to an etchant comprising oxygen, for example ozone (O3). In some examples, the substrate may be exposed to an etchant at a temperature of between about 25° C. and about 600° C., between about 100° C. and about 550° C., or between about 150° C. and about 450° C. In some examples, the etchant may be supplied in one continuous pulse or may be supplied in multiple shorter pulses.

The etching process may continue until the passivation layer 309 is substantially removed having a desired thickness of less than about 2 Å, or less than about 1 Å, or a negligible thickness or completely removed.

In particular embodiments, surfaces 304 and 306, and 344 may comprise various topologies within a device including but not limited to lateral structures, 2D or 3D structures, within a gap feature, where surfaces 304 and 306 are parallel, and/or at various angles to one another and/or adjacent to one another and/or in repeating patterns, or the like or combinations thereof.

In some examples of the disclosure, first surface 304 may comprise copper or cobalt, or a combination thereof, second surface 306 may comprising a low-k dielectric and third material layer 344 may comprise a molybdenum film.

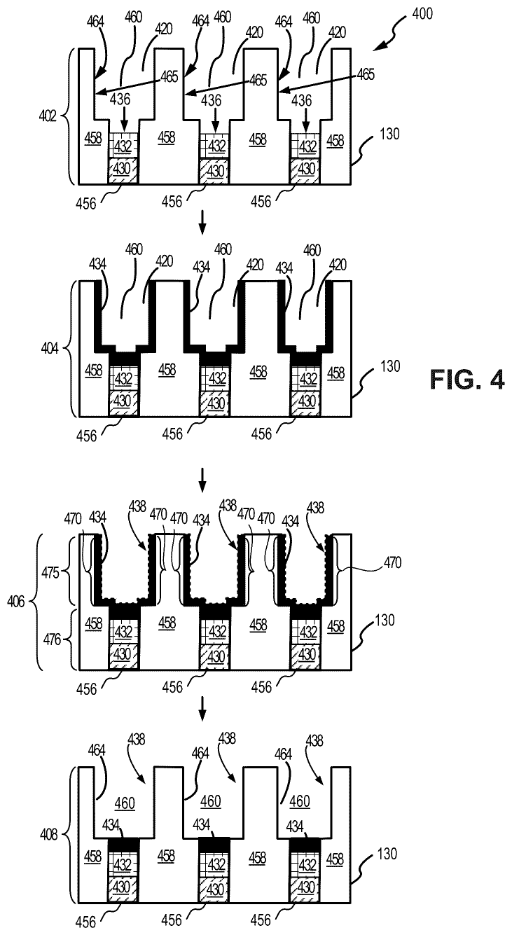

FIG. 4 illustrates simplified cross-sectional schematic diagrams of dual damascene features 420 formed in substrate 130. In an example, dual damascene features 420 may be fabricated during back-end-of-line (BEOL) processing. The dual damascene features 420 each comprise a via 456 contiguous with a trench 460. Vias 456 may be partially filled with a first material layer 430 and a second material layer 432. First material layer 430 and second material layer 432 may comprise different materials. Trenches 460 and vias 456 are formed in dielectric material 458.

Process 400 includes a first cyclic deposition sub-cycle to deposit a third metal layer 434 on second layer 432 within via 456; an oxidation sub-cycle to oxidize a portion of the third metal layer 434; and an etch back sub-cycle to remove a portion of the a third metal layer 434 deposited in unwanted areas such as a portion of trench 460 leaving a remainder of third metal layer 434 in via 456.

Process 400 begins with operation 402 where substrate 130 may be provided into a processing chamber (e.g., chamber 104 in FIG. 1). In an example, substrate 130 may have one or more dual damascene features 420 fabricated in an accessible portion of the substrate.

In an example, dual damascene features 420 further includes sidewalls 464 formed in dielectric material 458 Sidewalls 464 each have sidewall surfaces 465. In some examples, dielectric material 458 and sidewalls 464 may comprise silicon containing dielectric materials and/or metal oxide dielectric materials such as, but not limited to, silicon (Si), silicon dioxide (SiO2), silicon sub-oxides, silicon nitride (Si3N4), silicon oxynitride (SiON), silicon oxycarbide (SiOC), silicon oxycarbide nitride (SiOCN), silicon carbon nitride (SiCN), aluminum oxide (Al2O3), hafnium oxide (HfO2), tantalum oxide (Ta2O5), zirconium oxide (ZrO2), titanium oxide (TiO2), hafnium silicate (HfSiOx), and lanthanum oxide (La2O3). In some examples, dielectric material 458 and sidewalls 464 comprise a low-k material, as described above with respect to FIG. 3.

Process 400 may proceed to operation 404, where a third material layer 434 may be selectively deposited by a first cyclic deposition process onto sidewalls 464 and within vias 456. In certain examples, third material layer 434 of material may be deposited by a conformal fill process wherein the thickness of the deposited material is substantially the same on all surfaces. In certain other examples, third material layer 434 of material may be deposited by a non-conformal fill process wherein the thickness of the deposited material is not substantially the same on all surfaces.

In some examples, first material layer 430 may comprise cobalt (Co) and/or copper (Cu) and second material layer 432 may comprise cobalt (Co) and/or copper (Cu). First material layer 430 and second material layer 432 may be different materials.

In an example, third material layer 434 may be a metal (e.g., including but not limited to Mo, Al, Cu, W, Co, Nb, Ru, Ti, Ta or V or any combination thereof), metal oxide (e.g., any metal oxide including but not limited to AlOx, CoOx, CrOx, GaOx, HfOx, MnOx, MoOx, NbOx, NiOx, RuOx, SiCOx, SiOx, TaOx, TiOx, WOx, ZnOx, or ZrOx, or any combination thereof), metal nitride (e.g., a metal nitride including but not limited to TaN, MoNx, WNx, or TiN or any combination thereof), metal carbide (e.g., metal carbides including but not limited to VCx, MoCx, NbCx, TaCx, TiCx, or WCx or any combination thereof), silicon oxynitrides or silicon oxycarbides, or any combination thereof or any other appropriate material.

A first deposition sub-cycle may comprise contacting substrate 130 with first precursor 115 to selectively deposit the third material layer 434 onto dielectric sidewall 464 surfaces 465 and on inner surfaces 436 of second material layer 432 within vias 456. The dielectric inner surfaces 465 of sidewalls 464 are adjacent to inner surfaces 436 of second material layer 432.

In an example, first deposition sub-cycle may comprise pulsing first vapor phase precursor 115 from reactant source vessel 110 to reaction chamber 104 via showerhead 108. In an example, first precursor 115 may comprise a metal halide precursor (e.g., MoO₂Cl₂) or a metal iodide precursor, or a metal bromide precursor. In particular examples, the metal halide precursor may comprise: molybdenum (IV) dichloride dioxide (MoO₂Cl₂), molybdenum tetrachloride (MoCl₄), molybdenum pentachloride (MoCl₅), molybdenum (V) trichloride oxide (MoOCl₃), molybdenum (VI) tetrachloride oxide (MoOCl₄), indium trichloride (InCl₃), tantalum pentachloride (TaCl₅), tungsten hexachloride (WCl₆), vanadium fluoride (VF₃), vanadium chloride (VCl₃), vanadium oxychloride (VOCl₃), zirconium tetrachloride (ZrCl₄), titanium tetrachloride (TiCl₄), titanium tetraiodide (TiI₄), titanium tetrabromide (TiBr₃), hafnium tetrachloride (HfCl₄), boron trichloride (BCl₃), aluminum trichloride (AlCl₃), silicon tetrachloride (SiCl₄), disilicon hexachloride (Si₂Cl₆), 2-methylcyclohexa-2,5-diene-1,4-diyl) bis(trimethylsilane) (Cl₃H₂₆Si₂), triethyl borate (B(OCH₂CH₃)₃), trisilicon octochloride (Si₃Cl₈), dichlorosilane (SiH₂Cl₂), NiCl₂ (TMPDA), gallium monochloride (GaCl), gallium trichloride (GaCl₃), or niobium pentachloride (NbCl₅), or the like or combinations thereof.

In some examples of the disclosure, contacting substrate 130 with first precursor 115 may comprise contacting the substrate for a time period of between about 0.01 seconds and about 60 seconds, or between about 0.05 seconds and about 10 seconds, or between about 0.1 seconds and about 5.0 seconds, or even between 0.2 seconds and 1 second, or any appropriate time period.

In an example, selective deposition of third material layer 434 at operation 404 may be carried out using a PEALD process. In such an example, contacting inner surface 436 comprising copper and/or cobalt and dielectric surface of sidewalls 464 with precursor 115 may comprise generating a plasma to activate precursor 115. The plasma may be generated remotely in an RPU (e.g., RPU 170) and transported to reaction chamber 104 via transport tube 180. Alternatively, a plasma may be generated in-situ by a direct plasma device (e.g., direct plasma device 175). The plasma may be formed by exciting a plasma gas source (e.g., plasma source gas 184, see FIG. 1). There are a variety of activated plasma species such as ions, electrons and radicals that may interact with precursor 115 to deposit third material layer 434 (e.g., molybdenum) on inner surfaces 436 comprising copper and/or cobalt and dielectric inner surfaces 465 of sidewalls 464. For example, the plasma generated may be an excited species comprising electrons, ions, radicals and/or atoms of hydrogen, argon, neon, krypton, nitrogen, helium, xenon, radon, chlorine, fluorine, or oxygen or a combination thereof. In an example, third material layer 434 may comprise molybdenum deposited using PEALD and first precursor 115 may comprise MoO₂Cl₂. Using the PEALD technique may allow for use of lower temperatures (e.g., less than about 400° C., or less than about 375° C., or less than about 350° C., or any appropriate temperature) to deposit molybdenum using various precursors including MoO₂Cl₂. In an example wherein third material layer 434 is molybdenum deposited on inner surface 436 comprising copper and/or cobalt and dielectric surface of sidewalls 464, use of a PEALD to deposit molybdenum with MoO₂Cl₂ may reduce etching or other damage to the inner surface 436 or deeper into the copper and/or cobalt layer.

Process 400 may move to operation 406, where exposed surface 438 of third material layer 434 maybe oxidized by oxidizer 131 contacting surface 438. Oxidizer 131 may comprise any of a variety of oxidizers including water (H₂O), hydrogen peroxide (H₂O₂), ozone (O₃), oxygen (O₂), O₂ plasma, alcohol, alkyl alcohol, ethanol, methanol, butanol, isobutanol, isopropanol, or the like or combinations thereof.

Selectively depositing the third material layer 434 may comprise depositing the film as an unwanted layer 470 on a portion of the inner surfaces 465 of sidewalls 464 of the trenches 460 where it is not desirable for the third material layer 434 to be deposited. In the current example it is not desirable for third material layer 434 to deposit in the upper region 475 of the dual damascene feature 420. The oxidizing sub-cycle may be tailored to target the unwanted layer 470 on the portion of the trench responsive to contacting the material layer 434 with an oxidizer 131. The flow of oxidizer 131 may contact the unwanted layer 470 of third material layer 434 proportionately more in the upper region 475 compared to a lower region 476 of the damascene feature 420 where third material layer 434 is also disposed in vias 456 and/or on surfaces 436. This may improve etching efficiency on well oxidized portions of unwanted layer 470 responsive to contacting the substrate 130 with the second precursor 117. Thus, the unwanted layer 470 may be removed more efficiently than a different lower portion of third material layer 434.

Oxidizer 131 may be a vapor operation reactant pulsed into chamber 104 or may be a plasma generated by a remote or direct plasma source. In an example, oxidizing surface 438 may improve an etch rate at operation 408.

Process 400 may move to operation 408 where third material layer 434 may be etched back from sidewalls 464, leaving remaining third material layer 434 to reside within vias 456.

In an example, the etching at operation 408 may start by contacting third material layer 434 with a halide (e.g., second precursor 117 in FIG. 1). Such an etchant can be useful in increasing or maintaining desired selectivity and has an added benefit of removing metal oxides from the substrate surface and/or cleaning dielectric material of residue. An exemplary etchant may include molybdenum pentachloride (MoCl₅). Other etchants may be used including other metal halides, such as tungsten chloride (WCl₅), chlorine (Cl₂), niobium chloride (NbCl₅), titanium tetrachloride (TiCl₄), vanadium tetrachloride (VCl₄), tantalum pentachloride (TaCl₅), hafnium tetrachloride (HfCl₄), niobium fluoride (NbF₅), tantalum chloride (TaCl₅), or tantalum fluoride (TaF₅), or NF₃, or the like or a combination thereof.

The etching sub-cycle may be carried out at temperatures higher than deposition of the third material layer 344 (e.g., greater than about 300° C., or greater than about 350° C., or greater than about 400° C., or any appropriate temperature).

In an example, a concentration of second precursor 117 may impact etching activity. In an example, reactant vessel 140 temperature may be maintained at about 100° C. to 150° C. to maintain a faster or desired etch rate. In an example, a higher reactant vessel 140 temperature provides a higher dose of second precursor 117. In certain examples, second precursor 117 may be exposed to a remote, indirect, or direct plasma prior to reaching the surface of the substrate.

In an example, operations 404, 406 and/or 408 may be repeated until a desired thickness of third material layer 434 is achieved and until third material layer 434 is etched completely from surface 460 or thinned to a negligible or otherwise acceptable thickness on surface 460. In an example, a first desired thickness of third material layer 344 disposed on inner surface 436 may be sufficient to at least partially fill the vias 456 from the inner bottom surface up. In particular examples, the first desired thickness of third material layer 344 disposed on inner surface 436 may be between about 2.0 angstrom (Å)-200.0 Å, or between about 3.0 Å-175.0 Å, or between about 4.0 Å-150.0 Å, or between about 5.0 Å-125.0 Å, or between about 6.0 Å-100.0 Å, or between about 10.0 Å-75.0 Å or any appropriate thickness. Whereas, a second desired thickness of third material layer 434 disposed on second surface 460 may be less than about 2 Å, or less than about 1 Å, or any appropriate thickness. In some embodiments, the etching sub-cycles would etch the third material layer 434 completely off of second surface 460.

In an example, process 300 may be a preferential deposition process and may entail preferentially depositing third material layer 434 on inner surface 436 relative to sidewalls 464 of dual damascene features 420 thus depositing more third material layer 434 on inner surface 436 relative to sidewalls 464.

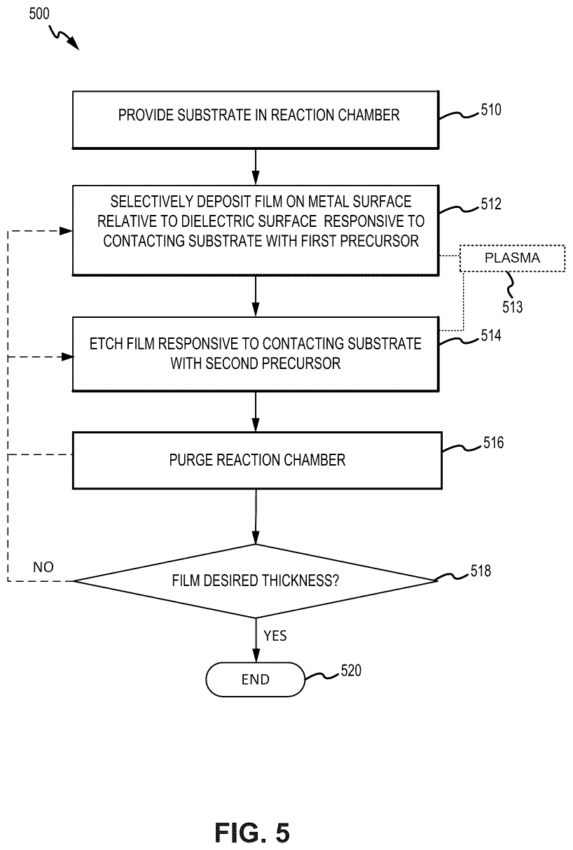

FIG. 5 illustrates a cyclic deposition process 500 for selective deposition of a molybdenum film.

Process 500 may begin at operation 510 where a substrate (e.g., substrate 130, FIG. 3) is supported in a reaction chamber (e.g., chamber 104, FIG. 1). In an example, the substrate 130 comprises a metal surface (e.g., see surface 310, FIG. 3, surface 436, FIG. 4) and adjacent to a dielectric surface (e.g., see, surface 314, FIG. 3 and sidewall 464 in FIG. 4). In an example, the metal surface may comprise copper (Cu) or cobalt (Co), or a combination thereof and the dielectric surface may comprise a low-k material as described hereinabove.

Process 500 may proceed to operation 512 where a metal film (e.g., molybdenum film) is selectively deposited on the metal surface relative to the dielectric surface responsive to contacting the substrate with a first precursor (e.g., first precursor 115, FIG. 1) containing a molybdenum oxyhalide. The selective deposition can be a cyclic deposition process. In an example, the first precursor may comprise a molybdenum halide such as MoO₂Cl₂. In an example, depositing the molybdenum film is carried out at a temperature less than about 350° C. In an example, at optional operation 513, depositing the metal film is carried out using plasma enhanced atomic layer deposition (PEALD) and/or at a first temperature less than about 350° C.

Process 500 may proceed to operation 514 where the metal film is etched responsive to contacting the substrate with a second precursor (e.g., precursor 117, FIG. 1). In an example, the second precursor may contain a molybdenum halide such as MoCl5. The etching process can be a cyclic etching process. In an example, etching the molybdenum film is carried out at a second temperature greater than about 350° C. In an example, etching the metal film is carried out using plasma enhanced atomic layer deposition (PEALD) at optional operation 513.

Process 500 may proceed to operation 516 where the chamber may be purged. A purge may be carried out before, between, and/or after each step of process 500.

Process 500 may proceed to operation 518 where operations 512, operation 514 and/or purge 516 are repeated until film reaches desired thickness on metal surface and dielectric surface.

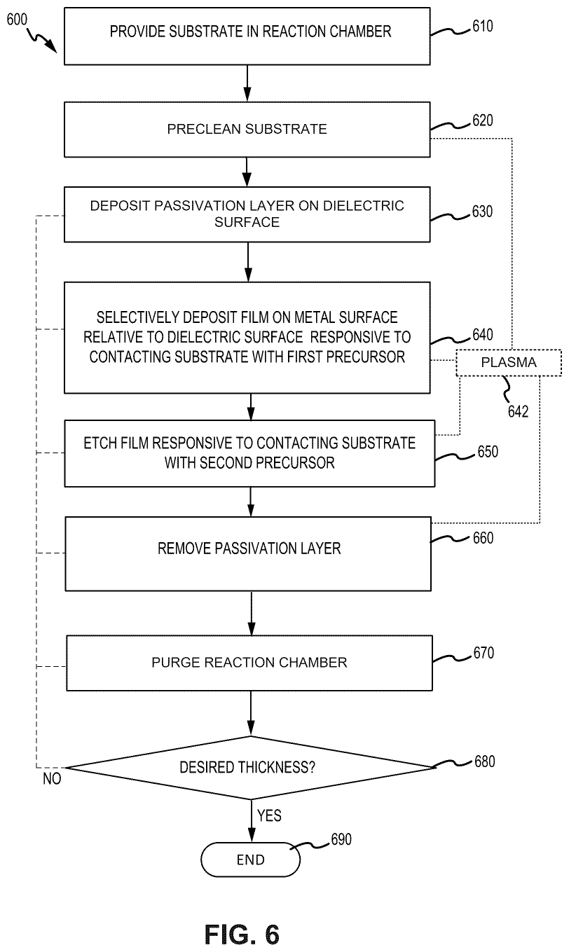

FIG. 6 illustrates an example cyclic deposition process 600 for selective deposition of a metal film on a metal surface relative to a dielectric surface.

Process 600 may begin at operation 610 where a substrate (e.g., substrate 130, FIG. 1) is supported in a reaction chamber (e.g., chamber 104, FIG. 1). In an example, the substrate 130 comprises a metal surface (e.g., see surface 310, FIG. 3, surface 436, FIG. 4) adjacent to a dielectric surface (e.g., see surface 314, FIG. 3 and sidewall 464 in FIG. 4). In an example, the metal surface may comprise copper (Cu) or cobalt (Co), or a combination thereof and the dielectric surface may comprise a low-k material as described hereinabove.

Process 600 may proceed to operation 620 where the metal surface and dielectric surface may be precleaned responsive to contacting the substrate with an etchant, for example, H2 plasma via optional operation 642.

Process 600 may proceed to operation 630 where a passivation film may be selectively deposited on the dielectric surface relative to the metal surface responsive to contacting the substrate with a second precursor comprising an alkylaminosilane. In some examples, the alkylaminosilane comprises at least one of allyltrimethylsilane (TMS-A), chlorotrimethylsilane (TMS-Cl), N-(trimethylsilyl) imidazole (TMS-Im), octadecyltrichlorosilane (ODTCS), hexamethyldisilazane (HMDS), N-(trimethylsilyl) dimethylamine (TMSDMA) or trimethylchlorosilane, or a combination thereof.

Process 600 may proceed to operation 640 where a metal film (e.g., molybdenum film) is selectively deposited on the metal surface relative to the dielectric surface responsive to contacting the substrate with a first precursor (e.g., first precursor 115, FIG. 1) containing a molybdenum oxyhalide. The selective deposition can be a cyclic deposition process. In an example, the first precursor may comprise a molybdenum halide such as MoO₂Cl₂. In an example, depositing the molybdenum film is carried out at a temperature less than about 350° C. In an example, depositing the metal film is carried out using plasma enhanced atomic layer deposition (PEALD) (e.g., via optional operation 642) and/or at a first temperature less than about 350° C.

Process 600 may proceed to operation 650 where the metal film is etched responsive to contacting the substrate with a second precursor (e.g., precursor 117, FIG. 1). In an example, the second precursor may contain a molybdenum halide such as MoCl5. The etching process can be a cyclic etching process. In an example, etching the metal film is carried out at a second temperature greater than about 350° C. In an example, etching the metal film is carried out using plasma enhanced atomic layer deposition (PEALD) (e.g., via optional operation 642). In an example, etching the metal film further comprises completely or partially removing the metal film that was deposited on the dielectric surface (e.g., see surface 314, FIG. 3 or sidewall 464 in FIG. 4) or the passivation film surface 326 of the passivation film 309 (see FIG. 3) during the cyclic deposition process. In an example, the passivation film may be removed responsive to contacting the substrate with a plasma (e.g., via optional operation 642).

In an example, etching of the metal film is carried out to remove the metal film from the dielectric surface (e.g., surface 310, FIG. 3) as well as preserving the metal film deposited and or disposed on the metal surface (e.g., surface 314, FIG. 3) of the substrate.

Process 600 may proceed to operation 660 where the passivation film 309 may be removed by variety of methods for example contacting substrate 130 with an H2 plasma or ozone.

Process 600 may proceed to operation 670 where the chamber may be purged. A purge may be carried out before, between, and/or after each operation of process 600. Each operation of process 600 maybe repeated any appropriate number of times. In an example, operations 640, 650 and/or 680 or a combination thereof may be repeated until the molybdenum film reaches a third desired thickness on the passivation film.

Process 600 may proceed to operation 680 where one or more of operations 630-670 may be repeated in any order until the metal film reaches desired thickness on metal surface and dielectric surface and has been sufficiently removed from the dielectric surface and/or passivation film surface as described in detail hereinabove.

Process 600 may end at block 690 upon determining that the metal film has reached a desired thickness.

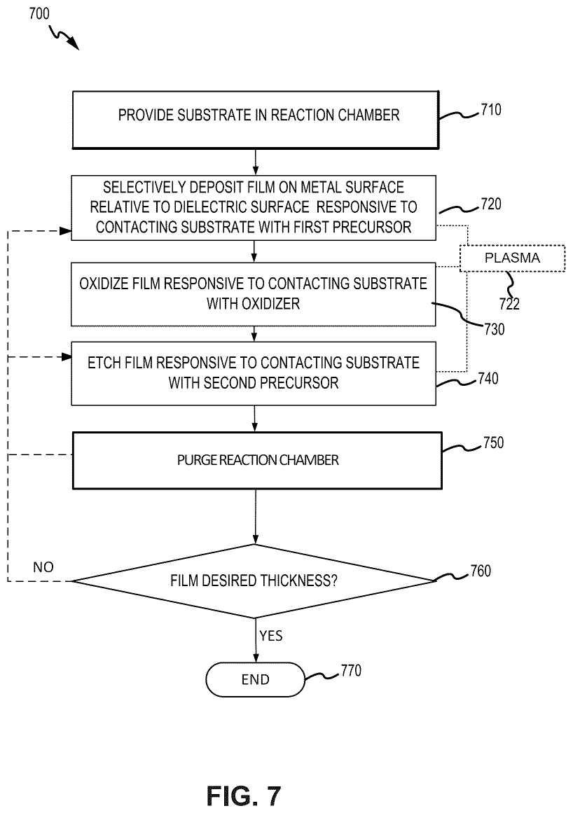

FIG. 7 illustrates a cyclic deposition process 700 for selective deposition of a molybdenum film.

Process 700 may begin at operation 710 where a substrate (e.g., substrate 130, FIG. 1) is supported in a reaction chamber (e.g., chamber 104, FIG. 1). In an example, the substrate has a dual damascene feature (e.g., dual damascene features 420, FIG. 4).

In an example, the substrate 130 comprises a metal surface (e.g., see metal surface 436, FIG. 4) adjacent to a dielectric surface (e.g., see, sidewall 464 in FIG. 4). In an example, the metal surface may comprise copper (Cu) or cobalt (Co), or a combination thereof and the dielectric surface may comprise a low-k material as described hereinabove.

Process 700 may proceed to operation 720 where a metal film (e.g., molybdenum film) is selectively deposited on the metal surface relative to the dielectric surface responsive to contacting the substrate with a first precursor (e.g., first precursor 115, FIG. 1). In some examples, the first precursor comprises a molybdenum oxyhalide. The selective deposition can be a cyclic deposition process. In an example, the first precursor may comprise a molybdenum halide such as MoO₂Cl₂.

In an example, selectively depositing the molybdenum film may comprise contacting the substrate with a first precursor within a feature on the substrate. The feature may be a via or trench, or combination thereof. In a dual damascene feature a via may be contiguous with a trench wherein the metal surface forms an inner surface of the via and wherein the dielectric surface forms inner sidewalls of the trench. In an example, selectively depositing the metal film may comprise depositing the metal film on the inner surface of the via to a thickness sufficient to at least partially fill the via from the inner surface up. Depositing the metal film on the inner surface of the via may result in deposition of the metal film on the inner side walls of the trench as well. It is unwanted or not desirable to have such deposition of metal film on the dielectric inner surface of the side walls within the trench. Thus, deposition results in an unwanted layer over a portion of the inner sidewalls in the trench. In an example, selectively depositing the molybdenum film is carried out at a temperature less than about 350° C.

In an example, at optional operation 722, depositing the metal film may be carried out using plasma enhanced atomic layer deposition (PEALD) and/or at a first temperature less than about 350° C. as described in detail hereinabove.

Process 700 may proceed to operation 730 where the metal layer may be oxidized. The ‘unwanted layer’ is in the upper region of the feature and will come into contact with the oxidizer more than lower regions. Thus, oxidizing the unwanted layer of the metal film responsive to contacting the metal film with an oxidizer will result in more oxidation in the upper region of the dual damascene feature.

In an example the oxidizer comprises at least one of: water (H₂O), hydrogen peroxide (H₂O₂), ozone (O₃), oxygen (O₂), O₂ plasma, alcohol, alkyl alcohol, ethanol, methanol, butanol, isobutanol, isopropanol, or a combination thereof. Oxidizing the metal surface improves the efficiency of an etching step.

Process 700 may proceed to operation 740 where a metal film and/or the unwanted layer may be etched. In an example, the metal film is etched responsive to contacting the substrate with a second precursor (e.g., precursor 117, FIG. 1). The second precursor may contain a molybdenum halide such as MoCl5. The etching process can be a cyclic etching process. In an example, etching the molybdenum film is carried out at a second temperature greater than about 350° C. In an example, etching the metal film is carried out using plasma enhanced atomic layer deposition (PEALD) at optional processing steps 722. Etching the unwanted layer may comprise removing substantially all of the unwanted layer.

The etching may be carried out at a first temperature above a second temperature at which the selective deposition proceeds.

Process 700 may proceed to operation 750 where the chamber may be purged. A purge may be carried out before, between, and/or after each step of process 700.

Process 700 may proceed to operation 760 where operations 720, 722, 730, 740 and/or 750 may be repeated any appropriate number of times, in any order, or a combination thereof until the unwanted layer has been etched to a desired thinness on the portion of the inner sidewalls of the trench and the portion of the metal layer within the via is a desired thickness.

Process 700 may end at block 770 upon determining that the metal film has reached a desired thickness.

It should be appreciated that any conceivable sequence of the deposition, etching processes, purge cycles, and repetitions thereof, is assumed as part of the present disclosure including combinations of deposition, etching processes, purge cycles, and repetitions thereof disclosed with respect to different FIGS. and claimed subject matter is not limited in this regard.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for selective deposition of a molybdenum film, comprising:
a) supporting a substrate in a reaction chamber, the substrate comprising a metal surface and an adjacent dielectric surface;
b) selectively depositing the molybdenum film on the metal surface relative to the dielectric surface responsive to contacting the substrate with a first precursor containing a molybdenum oxyhalide in a cyclic deposition process;
c) etching the molybdenum film responsive to contacting the substrate with a second precursor containing molybdenum halide in a cyclic etching process; and
d) purging the reaction chamber.

2. The method of claim 1, further comprising repeating steps b, c, or d or a combination thereof until the molybdenum film reaches a first desired thickness on the metal surface.

3. The method of claim 1, further comprising repeating steps b, c, or d or a combination thereof until the molybdenum film reaches a second desired thickness on the dielectric surface.

4. The method of claim 1, wherein the metal surface comprises copper (Cu) or cobalt (Co), or a combination thereof.

5. The method of claim 1, wherein the dielectric surface comprises low-k material.

6. The method of claim 1, wherein the first precursor contains MoO₂Cl₂ and wherein the second precursor contains MoCl₅.

7. The method of claim 6, wherein selectively depositing the molybdenum film is carried out using plasma enhanced atomic layer deposition (PEALD) at a temperature less than about 350° C.

8. The method of claim 6, wherein etching the molybdenum film is carried out at a temperature greater than about 350° C.

9. The method of claim 1, further comprising precleaning the metal surface and dielectric surface responsive to contacting the substrate with an H₂ plasma.

10. The method of claim 1, further comprising selectively depositing a passivation film on the dielectric surface relative to the metal surface responsive to contacting the substrate with a second precursor comprising an alkylaminosilane.

11. The method of claim 10, wherein the passivation film is deposited prior to the selectively depositing the molybdenum film.

12. The method of claim 10, wherein the alkylaminosilane comprises at least one of allyltrimethylsilane (TMS-A), chlorotrimethylsilane (TMS-Cl), N-(trimethylsilyl) imidazole (TMS-Im), octadecyltrichlorosilane (ODTCS), hexamethyldisilazane (HMDS), N-(trimethylsilyl) dimethylamine (TMSDMA) or trimethylchlorosilane, or a combination thereof.

13. The method of claim 10, wherein the etching the molybdenum film further comprises removing the molybdenum film that deposited on the passivation film during the cyclic deposition process.

14. The method of claim 10, repeating steps b, c, or d, or a combination thereof until the molybdenum film reaches a third desired thickness on the passivation film.

15. The method of claim 14, further comprising removing the passivation film responsive to contacting the substrate with a plasma.

16. The method of claim 1, wherein contacting the substrate with a first precursor takes place within a feature.

17. The method of claim 16, wherein the feature is a via or trench, or combination thereof.

18. The method of claim 16, wherein the feature is a dual damascene feature having a via contiguous with a trench.

19. The method of claim 18, wherein the metal surface forms an inner surface of the via and wherein the dielectric surface forms inner sidewalls of the trench.

20. The method of claim 19, wherein the selectively depositing the molybdenum film further comprises depositing the molybdenum film on the inner surface of the via to a thickness sufficient to at least partially fill the via from the inner surface up.

21. The method of claim 19, wherein the selectively depositing the molybdenum film further comprises depositing the molybdenum film in an unwanted layer on a portion of the inner sidewalls of the trench.

22. The method of claim 21, further comprising:
e) oxidizing the unwanted layer of the molybdenum film on the portion of the trench responsive to contacting the molybdenum film with an oxidizer; and
f) etching the unwanted layer responsive to contacting the substrate with the second precursor.

23. The method of claim 22, repeating steps e or f or a combination thereof until the unwanted layer has been etched to a desired thinness on the portion of the inner sidewalls of the trench.

24. The method of claim 22, wherein the etching the unwanted layer further comprises removing substantially all of the unwanted layer.

25. The method of claim 22, wherein the oxidizer comprises at least one of: water (H₂O), hydrogen peroxide (H₂O₂), ozone (O₃), oxygen (O₂), O₂ plasma, alcohol, alkyl alcohol, ethanol, methanol, butanol, isobutanol, isopropanol, or a combination thereof.

26. The method of claim 22, wherein the etching is carried out at a first temperature above a second temperature at which the selective deposition is carried out.

27. The method of claim 21, wherein the selectively depositing the molybdenum film further comprises a plasma enhanced atomic layer (PEALD) deposition process, comprising, alternately and sequentially contacting the substrate with the first precursor containing MoO₂Cl₂and a reactant comprising reactive species from a plasma.

28. The method of claim 27, wherein the reactive species is H₂.
